(19) United States
(12) Patent Application Publication
(10) Pub. No.: US 2017/0055371 A1
(43) Pub. Date: Feb. 23, 2017

(54) COOLING APPARATUS AND ELECTRONIC EQUIPMENT

(71) Applicant: FUJITSU LIMITED, Kawasaki-Shi (JP)

(72) Inventor: Marco Scifoni, Kawasaki (JP)

(73) Assignee: FUJITSU LIMITED, Kawasaki-shi (JP)

(21) Appl. No.: 15/213,610

(22) Filed: Jul. 19, 2016

(30) Foreign Application Priority Data
Aug. 20, 2015 (JP) 2015-162526

(51) Int. Cl. H05K 7/20

(52) U.S. Cl. CPC H05K 7/20336

(57) ABSTRACT

A cooling apparatus includes: a plurality of evaporation chambers in which a refrigerant is accommodated; a steam path including a plurality of steam path branch portions which extend from the plurality of evaporation chambers, respectively, and a steam path body portion in which the plurality of steam path branch portions join with each other; a condensing chamber coupled to the plurality of evaporation chambers through the steam path; a liquid path including a liquid path body portion which extends from the condensing chamber, and a plurality of liquid path branch portions, which are branched from the liquid path body portion to be coupled to the plurality of evaporation chambers, respectively; and a check valve installed in the steam path and suppresses a reverse flow of the refrigerant from one evaporation chamber to another evaporation chamber among the plurality of evaporation chambers.

### CROSS-REFERENCE TO RELATED APPLICATION

This application is based upon and claims the benefit of priority of the prior Japanese Patent Application No. 2015-162526, filed on Aug. 20, 2015, the entire contents of which are incorporated herein by reference.

### FIELD

The embodiments discussed herein are related to a cooling apparatus and electronic equipment.

### BACKGROUND

As a technique of cooling a heat generation unit installed in, for example, electronic equipment, there is a loop heat pipe which includes an evaporator, a condenser, and a steam pipe and a liquid pipe which connect the evaporator and the condenser to each other.

In the loop heat pipe, when a refrigerant within the evaporator is vaporized by the heat of the heat generation unit, the vaporized refrigerant is conveyed from the evaporator to the condenser through the steam pipe. The refrigerant conveyed through the steam pipe is liquefied in the condenser, and the refrigerant liquefied in the condenser is returned to the evaporator from the condenser through the liquid pipe. Then, as described above, the refrigerant is circulated between the evaporator and the condenser such that the heat of the heat generation unit is transported by the refrigerant from the evaporator to the condenser. As a result, the heat generation unit is cooled.

However, in the electronic equipment, when a plurality of heat generation units are cooled, it is considered to use a plurality of evaporators corresponding to the plurality of heat generation units, respectively. In the case of using the plurality of evaporators as described above, when condensers are used for the plurality of evaporators, respectively, the number of the condensers increases thereby deteriorating mounting efficiency.

Thus, in order to solve this problem, it is considered to use a common condenser for a plurality of evaporators. In this case, each of the evaporator side of the steam pipe and the evaporator side of the liquid pipe is branched into a plurality of branch pipes, and the evaporators are connected to the plurality of branch pipes, respectively.

However, in this structure, when a pressure difference occurs among the plurality of evaporators due to a difference in heat flows received by the plurality of evaporators, the refrigerant may reversely flow from a high pressure evaporator to a low pressure evaporator. When the refrigerant reversely flows from the high pressure evaporator to the low pressure evaporator, the reversely flowing refrigerant and the refrigerant flowing out from the low pressure evaporator may interfere with each other, and the boiling of the refrigerant in the low pressure evaporator may be delayed so that the low pressure evaporator may not start to operate smoothly. Further, when the evaporator does not start to operate smoothly, a cooling performance for the heat generation unit corresponding to the evaporator may be damaged, and the temperature of the heat generation unit may be excessively increased.

The followings are reference documents.
[Document 1] Japanese Laid-Open Patent Publication No. 2013-057439,
[Document 2] Japanese Laid-Open Patent Publication No. 3-273669, and
[Document 3] Japanese Laid-Open Patent Publication No. 2006-242176.

### SUMMARY

According to an aspect of the invention, a cooling apparatus includes: a plurality of evaporation chambers in which a refrigerant is accommodated; a steam path including a plurality of steam path branch portions which extend from the plurality of evaporation chambers, respectively, and a steam path body portion in which the plurality of steam path branch portions join with each other; a condensing chamber coupled to the plurality of evaporation chambers through the steam path; a liquid path including a liquid path body portion which extends from the condensing chamber, and a plurality of liquid path branch portions, which are branched from the liquid path body portion to be coupled to the plurality of evaporation chambers, respectively; and a check valve installed in the steam path and suppresses a reverse flow of the refrigerant from one evaporation chamber to another evaporation chamber among the plurality of evaporation chambers.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view of electronic equipment of an embodiment of the present disclosure;

FIG. 2 is an exploded perspective view of the plug-in unit;

FIG. 3 is a plan view of the cooling apparatus;

FIG. 4 is a vertical cross-section of the laminated structure;

FIG. 5 is a perspective view of the check valve;

FIG. 6 is a three-plane view of the check valve;

FIG. 7 is a vertical cross-section of the laminated structure;

FIG. 8 is a horizontal cross-section of the laminated structure;

FIG. 9 is a vertical cross-section of the cooling apparatus;

FIG. 10 is a horizontal cross-section of the cooling apparatus;

FIG. 11 is a view illustrating a case where pressures of a plurality of evaporation chambers in the cooling apparatus are the same;

FIG. 12 is a view illustrating a case where pressures of the plurality of evaporation chambers in the cooling apparatus are different from each other;

FIG. 13 is a view illustrating a first modification of the cooling apparatus;

FIG. 14 is a view illustrating a second modification of the cooling apparatus;

FIG. 15 is a view illustrating a third modification of the cooling apparatus;

FIG. 16 is a view illustrating a fourth modification of the cooling apparatus;

FIG. 17 is a view illustrating a fifth modification of the cooling apparatus;

FIG. 18 is a view illustrating a sixth modification of the cooling apparatus;

FIG. 19 is a view illustrating a modification of the electronic equipment;

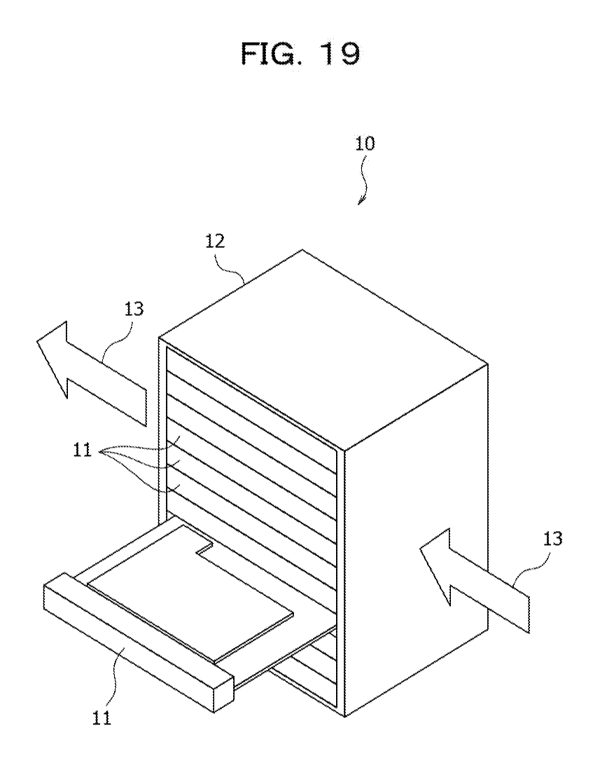

FIG. 20 is a plan view of a cooling apparatus according to a comparative example; and

FIG. 21 is a view illustrating characteristics of the cooling apparatus according to the comparative example.

### DESCRIPTION OF EMBODIMENTS

Hereinafter, an embodiment of a technology disclosed herein will be described.

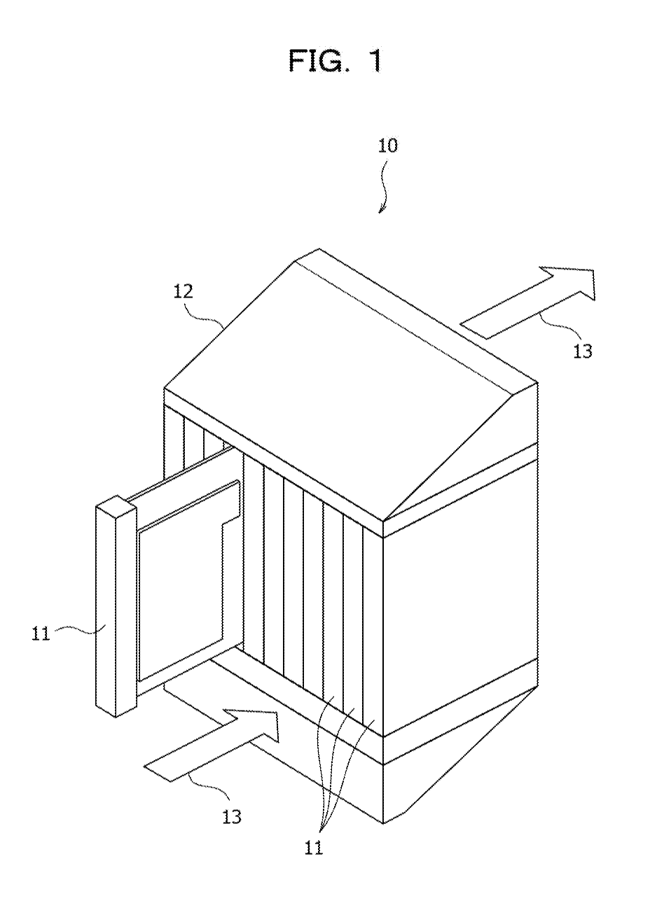

As illustrated in FIG. 1, electronic equipment 10 according to the embodiment is of, for example, a book shelf type, and includes a plurality of plug-in units 11. The plurality of plug-in units 11 are arranged individually vertically and installed side by side in the horizontal width direction of the electronic equipment 10. The electronic equipment 10 of the present embodiment is, for example, information and communication technology (ICT) equipment. The inside of a housing 12 of the electronic equipment 10 is subject to natural air cooling or forced air cooling by allowing cooling air 13 to pass therethrough.

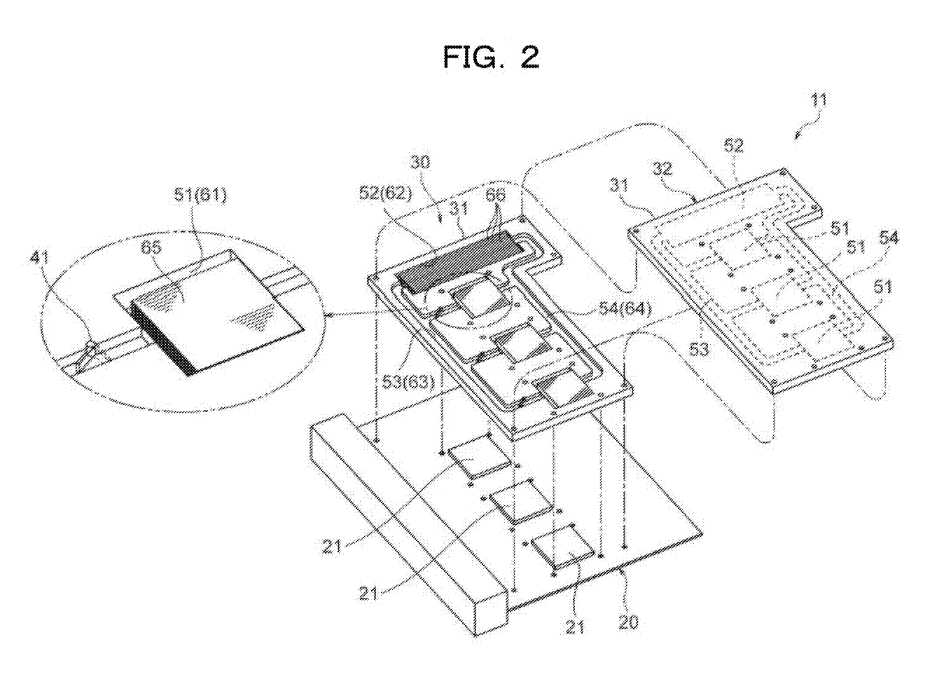

As illustrated in FIG. 2, each plug-in unit 11 includes a printed circuit board 20 and a cooling apparatus 30. A plurality of heat generating bodies 21 such as, for example, electronic parts, are mounted on the printed circuit board 20. The number of heat generating bodies 21 is, for example, three (3). Each heat generating body 21 is an example of a “heat generation unit” and generates heat during the operation thereof.

The cooling apparatus 30 is mounted on the printed circuit board 20. The cooling apparatus 30 includes a pair of plates 31 and a plurality of check valves 41.

The pair of plates 31 is laminated to form a thin laminate 32. The pair of plates 31 are formed of, for example, a metal and bonded to each other by diffusion bonding.

The pair of plates 31 is formed to be plane-symmetric with each other. Recesses 51 and 52 and grooves 53 and 54 are formed in each plate 31. The recesses 51 and 52 and the grooves 53 and 54 formed in one plate 31 match with the recesses 51 and 52 and the grooves 53 and 54 formed in the other plate 31 in position and shape.

When the pair of plates 31 is bonded to each other, the recesses 51 and 52 and the grooves 53 and 54 formed in one plate 31 fit with the recesses 51 and 52 and the grooves 53 and 54 formed in the other plate 31 so as to form cavities inside the laminate 32. The cavities form evaporation chambers 61, a steam path 63, a condensing chamber 62, and a liquid path 64 as described later.

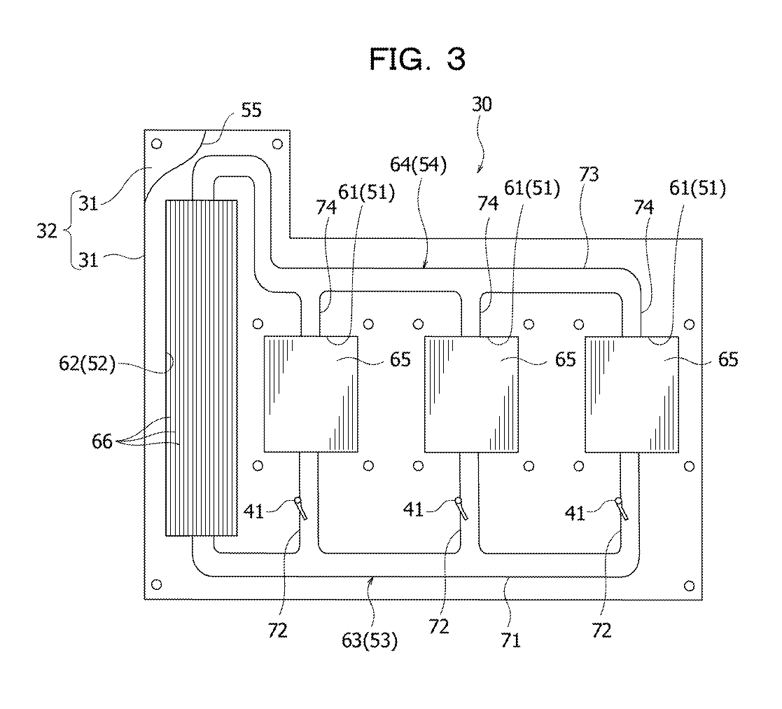

FIG. 3 illustrates a plan view of the cooling apparatus 30. FIG. 3 illustrates the upper plate 31 in a state where the upper plate 31 is cut along a cutting line 55 in order to facilitate the understanding of the internal structure of the cooling apparatus 30. As illustrated in FIG. 3, each of the plurality of recesses 51 and 52 is formed in a square shape in a plan view. The plurality of recesses 51 form the evaporation chambers 61, respectively. The recess 52 forms the condensing chamber 62. The plurality of evaporation chambers 61 are formed in the same dimension and the same shape.

In addition, one groove 53 forms the steam path 63, and the other groove 54 forms the liquid path 64. The steam path 63 includes a steam path body portion 71 and a plurality of steam path branch portions 72. The plurality of steam path branch portions 72 extend from the plurality of evaporation chambers 61, respectively, and join with each other at one end side of the steam path body portion 71. The other end side of the steam path body portion 71 is connected to the condensing chamber 62.

Similarly, the liquid path 64 includes a liquid path body portion 73 and a plurality of liquid path branch portions 74. The liquid path body portion 73 extends from the condensing chamber 62. The plurality of liquid path branch portions 74 are branched from the liquid path body portion 73 and connected to the plurality of evaporation chambers 61, respectively. The outlets of the plurality of evaporation chambers 61 are connected to the inlet of the condensing chamber 62 through the steam path 63. The outlet of the condensing chamber 62 is connected to each of the plurality of evaporation chambers 61 through the liquid path 64.

Each of the plurality of evaporation chambers 61 accommodates a wick 65 therein. The condensing chamber 62 is provided with a plurality of heat dissipation fins 66. Each of the plurality of evaporation chambers 61 also accommodates a refrigerant therein. The plurality of evaporation chambers 61 are arranged at positions corresponding to the plurality of heat generating bodies 21, respectively, in the state in which the cooling apparatus 30 is mounted on the printed circuit board 20 represented in FIG. 2. The portions of the laminate 32 where the plurality of evaporation chambers 61 are formed are thermally connected to the plurality of heat generating bodies 21 via, for example, thermal sheets.

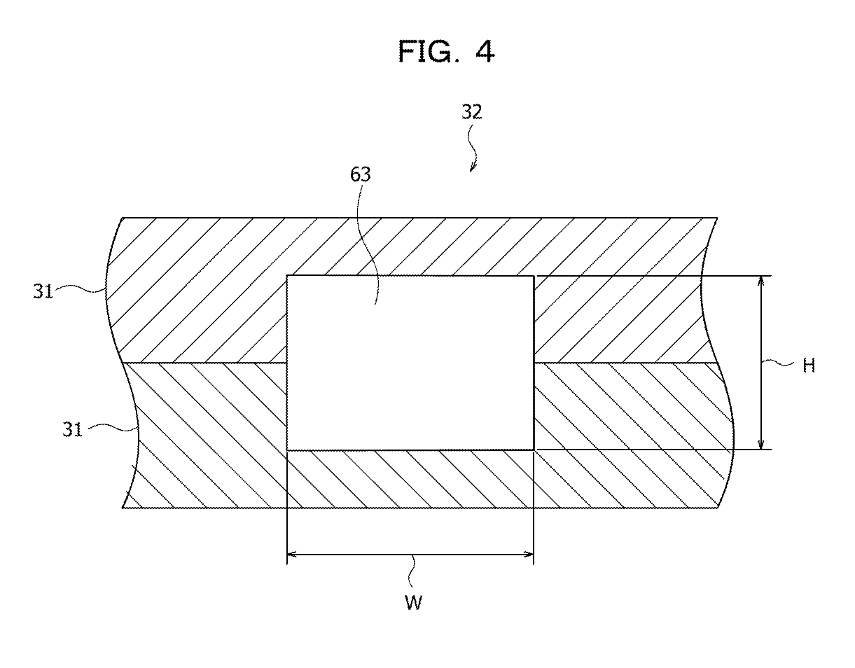

Each of the above-described evaporation chambers 61, steam path 63, condensing chamber 62, and liquid path 64 is formed in a square shape in cross section. In addition, the laminate 32, which includes the evaporation chambers 61, the steam path 63, the condensing chamber 62, and the liquid path 64, is formed in a thin flat shape. Hence, as illustrated in FIG. 4, for example, the dimension of the steam path 63 W in the width direction is larger than the dimension of the steam path 63 H in the height direction.

The plurality of check valves 41 represented in FIGS. 2 and 3 are to suppress a reverse flow of a refrigerant from one of the plurality of evaporation chamber 61 into the other one of the plurality of evaporation chambers 61. The plurality of check valves 41 are swing type check valves, and are installed in the plurality of steam path branch portions 72, respectively. In the present embodiment, the plurality of check valves 41 is formed in the same shape.

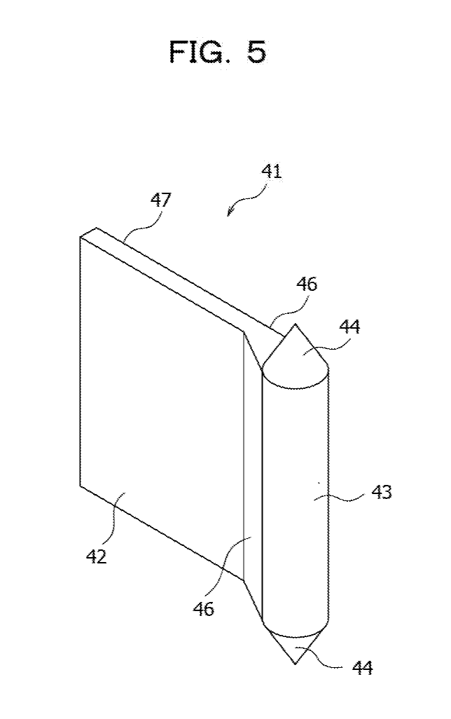

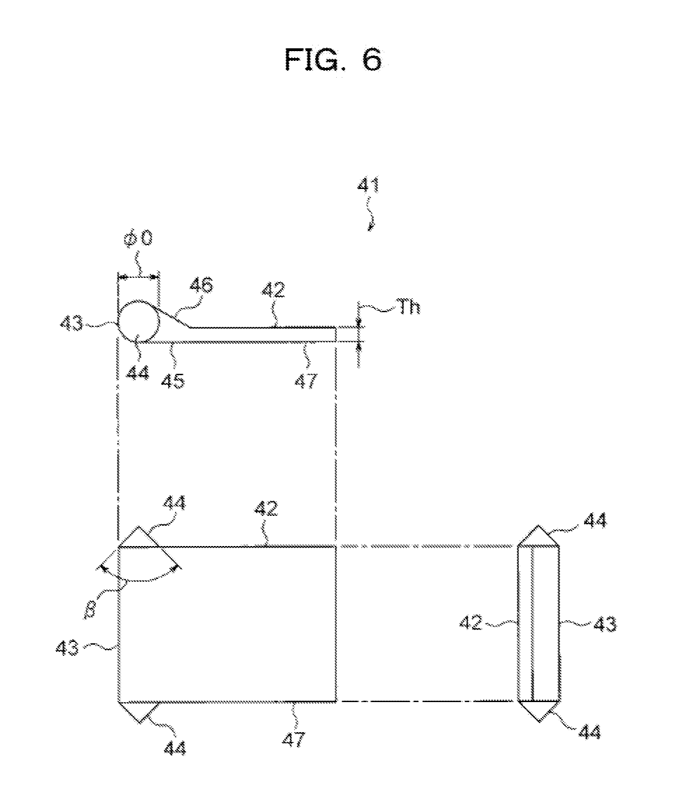

As illustrated in FIGS. 5 and 6, each check valve 41 includes a valve body 42 and a shaft portion 43. The valve body 42 is formed in a square plate shape. The shaft portion 43 is formed along one edge (base end) of the valve body 42. Insertion portions 44, each having a conically convex shape are formed at the axial opposite ends of the shaft portion 43, respectively.

As illustrated in FIG. 6, in the check valve 41, the thickness Th of the valve body 42 becomes thinner than the diameter φD of the shaft portion 43. The check valve 41 may be formed of a material having higher hardness than that of the above-described pair of plates 31 (see, e.g., FIG. 2). In the present embodiment, the check valve 41 is formed of, for example, ceramic or carbide.

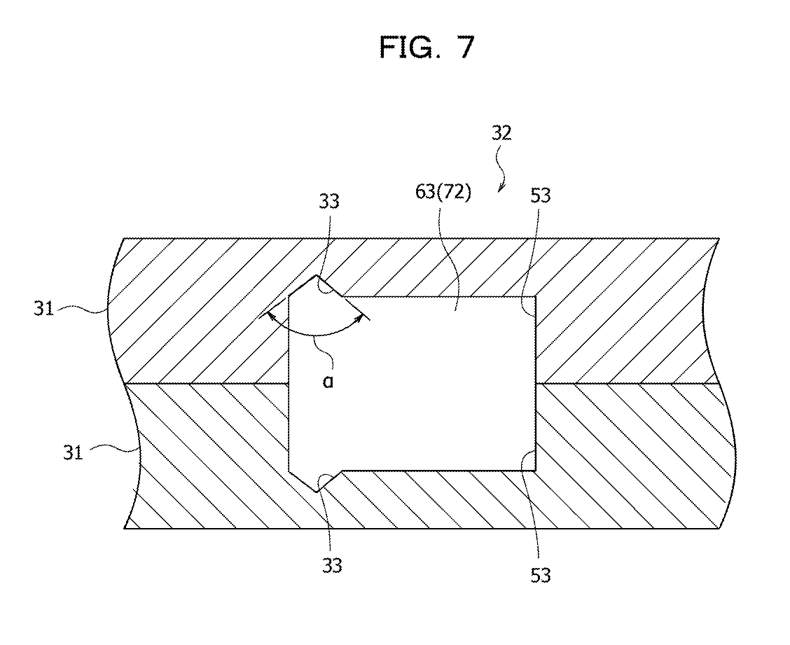

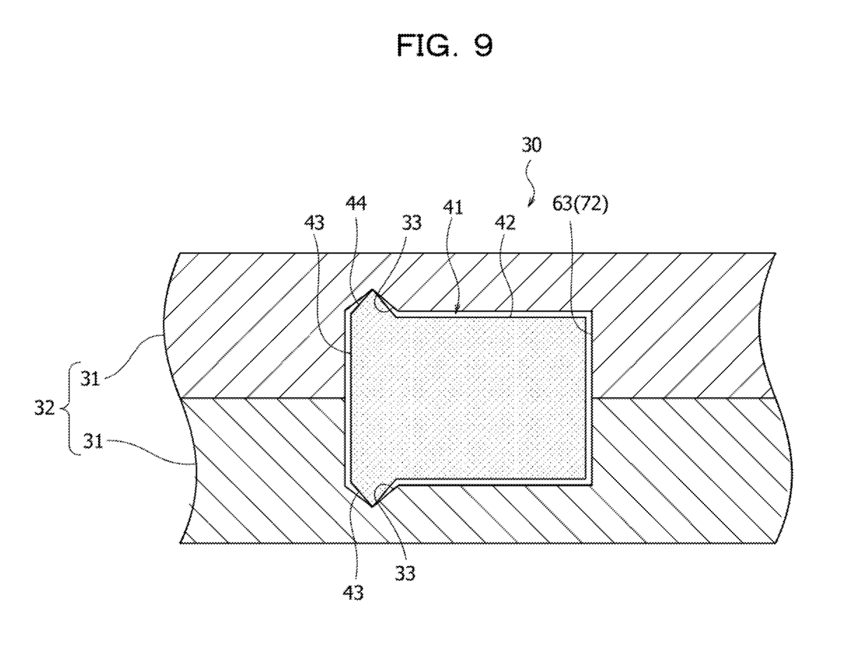

As illustrated in FIG. 7, the pair of plates 31 are provided with a pair of pivotal support portions 33 each having a conically concave shape. The pair of pivotal support portions 33 is formed at the bottom surfaces of the pair of grooves 53, respectively, which form a steam path branch portion 72. As illustrated in FIG. 9, the shaft portion 43 extends in the thickness direction of the laminate 32 (the pair of plates 31), and the insertion portions 44 formed at the axial opposite ends of the shaft portion 43 are inserted into the pivotal support portions 33, respectively.

The spreading angle of the inner peripheral surface of each pivotal support portion 33α (see, e.g., FIG. 7) is set to be, for example, about 10° larger than the apical angle of each insertion portion 44 β (see, e.g., FIG. 6). The tip ends of the insertion portions 44 are in point-contact with the bottoms of the pivotal support portions 33, respectively. The shaft portions 43 and the pivotal support portions 33 form a hinge, and the shaft portions 43 are rotatably supported by the pivotal support portions 33 in the state in which the tip ends of the insertion portions 44 are in point-contact with the bottoms of the pivotal support portions 33, respectively.

Because the shaft portions 43 are rotatably supported by the pivotal support portions 33, the check valve 41 is adapted to be swingable. In addition, because the check valve 41 swings, the steam path 63 is opened and closed by the valve body 42. The check valve 41 operates by receiving the pressure of the refrigerant in the steam path 63.

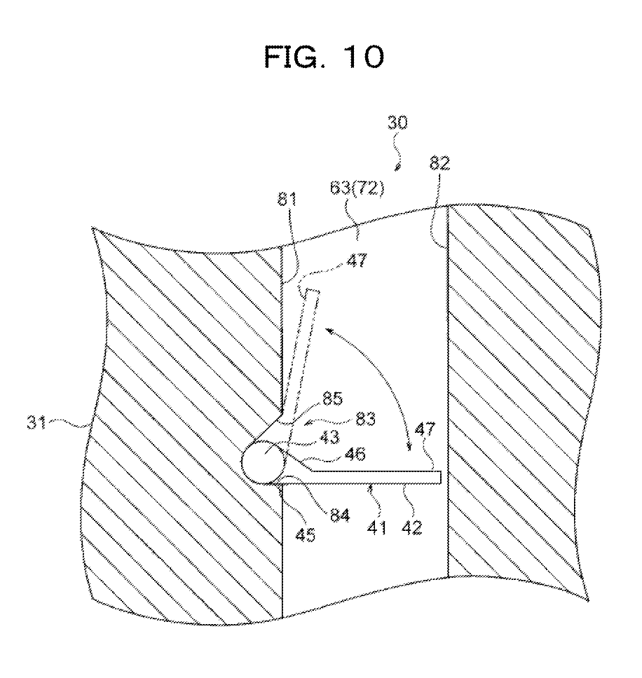

In FIG. 10, the closed state of the check valve 41 is represented by a solid line, and the opened state of the check valve 41 is represented by an imaginary line (a long and two short dashed line). The shaft portion 43 is disposed at one side of the steam path 63 in the width direction thereof. The valve body 42 extends from the shaft portion 43 toward the other side of the steam path 63 in the width direction thereof in the closed state of the check valve 41. In addition, the valve body 42 is formed in a rectangular shape of which a longitudinal direction is orthogonal to the axial direction of the shaft portion 43.

In the closed state, the check valve 41 is brought into a state of extending toward the normal line direction of one side surface 81 of a pair of side surfaces 81 and 82 formed in the steam path branch portion 72 (i.e., the direction orthogonal to the longitudinal direction of the steam path 63). In addition, the check valve 41 is rotated in a direction approaching the side surface 81 to be brought into the opened state. The side surface 81 is an example of “one of four inner wall surfaces which form the square shape of the steam path in cross section.”

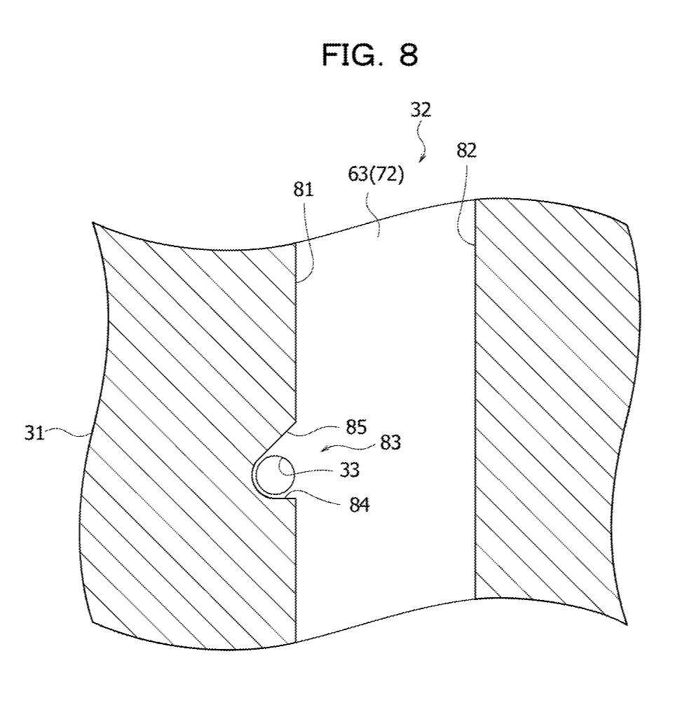

As illustrated in FIG. 8, a recessed accommodation portion 83 is formed on the above-described side surface 81, and each of the pivotal support portions 33 is disposed inside the accommodation portion 83 in a plan view. Accordingly, as illustrated in FIG. 10, each shaft portion 43 is rotatably accommodated in the accommodation portion 83.

A stopper portion 84 and a regulation portion 85 are formed on the inner wall surface of the recessed accommodation portion 83. As represented by a solid line in FIG. 10, the stopper portion 84 is in contact with one side surface 45 of the base end of the valve body 42 in the closed state of the check valve 41. Meanwhile, as represented by an imaginary line in FIG. 10, the regulation portion 85 is in contact with the other side surface 46 of the base end of the valve body 42 in the opened state of the check valve 41.

The other side surface 46 of the base end of the valve body 42 is an inclined surface and is inclined toward one side surface 45 as being directed toward the tip end of the valve body 42 from the base end thereof. In addition, the other side surface 46 is inclined to regulate the angle of the check valve 41 in the opened state. When the check valve 41 is brought into the opened state, the tip end 47 of the valve body 42 is spaced apart from one side surface 81 of the steam path branch portion 72 and brought into a state of being inclined toward the inside of the steam path branch portion 72, compared to the other side surface 46 of the valve body 42.

In addition, when the refrigerant reversely flows, the refrigerant flows into a gap between the check valve 41 and the side surface 81, and a moment acts on the check valve 41 so that the check valve 41 is quickly closed. The inclination angle of the check valve 41 in the opened state is set by the inclination angles of the other side surface 46 of the base end of the valve body 42 and the regulation portion 85. The inclination angle of the check valve 41 is arbitrarily set so that detection accuracy of the check valve 41 in the case of the reverse flow of the refrigerant is adjusted.

In addition, for example, as the inclination of the check valve 41 toward the steam path branch portion 72 increases when the check valve 41 is brought into the opened state, the check valve 41 is easily closed even with a small reverse flow amount of the refrigerant, but a pressure loss increases when the refrigerant forwardly flows. Thus, for example, when the refrigerant is highly viscous, the moment acting on the check valve 41 increases, and hence, the inclination of the check valve 41 may be set to be small.

In addition, the inclination of the check valve 41 may be also set to be small in a case of attempting to reduce and suppress the pressure loss when the refrigerant forwardly flows. In addition, in a case in which it is assumed that the reverse flow amount of the refrigerant is small, and it is required to close the check valve 41 with good sensitivity, the inclination of the check valve 41 may be set to be large.

Next, the operation of the cooling apparatus 30 of the present embodiment will be described.

(When calorific values received by the plurality of evaporation chambers 61 are the same)

First, descriptions will be made on a case where heat flows received by the plurality of evaporation chambers 61 are the same.

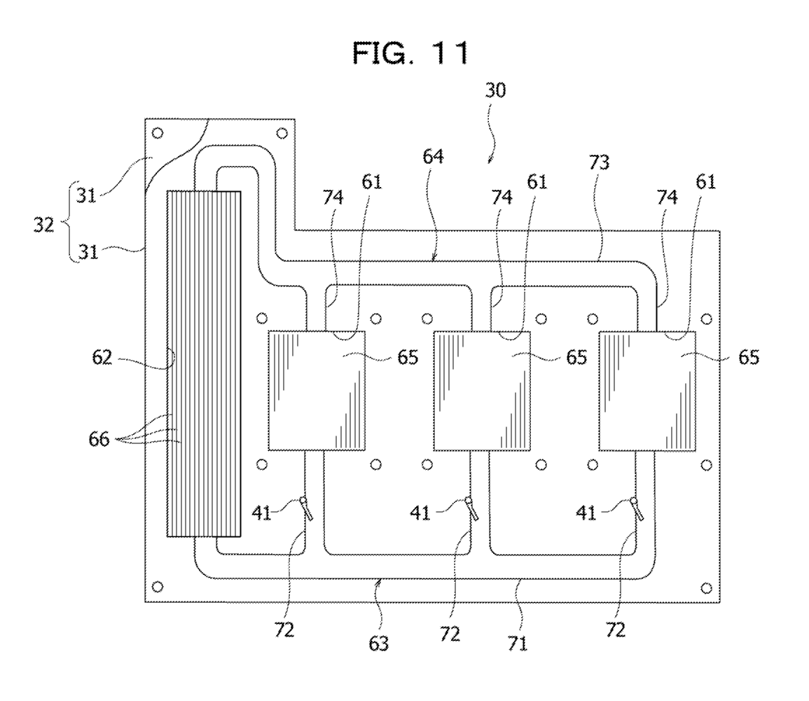

When the heat generating state of the plurality of heat generating bodies 21 is balanced, the heat flows received by the plurality of evaporation chambers 61 become the same, and the pressures of the plurality of evaporation chambers 61 also become the same. Here, FIG. 11 represents a case where the pressures of the plurality of evaporation chambers 61 are the same. As illustrated in FIG. 11, when the pressures of the plurality of evaporation chambers 61 are the same, all the plurality of check valves 41 are brought into the opened state.

In addition, when the pressures of the plurality of evaporation chambers 61 are the same, the flow rates of the refrigerants flowing out from the plurality of evaporation chambers 61 also become equal to each other, and the thermos-dynamical states at the joining portions of the steam path branch portions 72 and the steam path body portion 71 also become the same. Hence, the refrigerants smoothly join with each other at the respective joining portions, and the interference of the refrigerants is suppressed so that the flow of the refrigerants is stabilized. Therefore, the plurality of evaporation chambers 61 are smoothly led to the normal operation.

Then, in the plurality of evaporation chambers 61, the refrigerants vaporized by the heat of the plurality of heat generating bodies 21 are conveyed from the plurality of evaporation chamber 61 to the condensing chamber 62 through the steam path 63 (the plurality of steam path branch portions 72 and the steam path body portion 71).

In the condensing chamber 62, the refrigerants conveyed through the steam path 63 are liquefied. The refrigerants liquefied in the condensing chamber 62 are returned to the plurality of evaporation chambers 61, respectively, from the condensing chamber 62 through the liquid path 64 (the liquid path body portion 73 and the plurality of liquid path branch portions 74).

Then, as described above, the refrigerants are circulated between the plurality of evaporation chambers 61 and the condensing chamber 62 so that the heat of the plurality of heat generating bodies 21 is transported by the refrigerants from the plurality of evaporation chambers 61 to the condensing chamber 62. As a result, the cooling performance for the plurality of heat generating bodies 21 is assured, and the plurality of heat generating bodies 21 are identically cooled.

(When heat flows received by the plurality of evaporation chambers 61 are different from each other)

Subsequently, descriptions will be made on a case where heat flows received by the plurality of evaporation chambers 61 are different from each other.

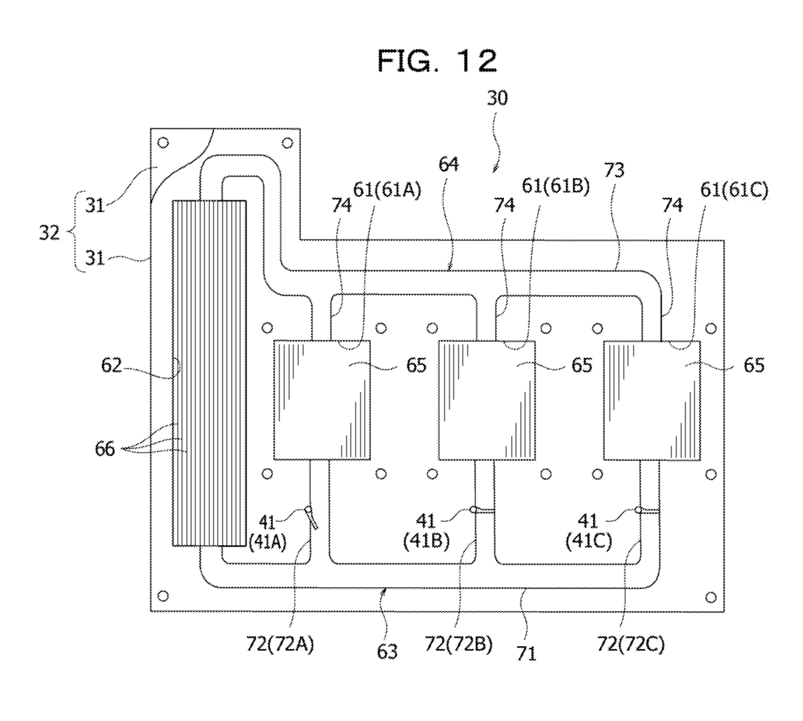

When the heat generating states of the plurality of heat generating bodies 21 are unbalanced, the heat flows received by the plurality of evaporation chambers 61 become different from each other so that a pressure difference occurs among the plurality of evaporation chambers 61. Here, FIG. 12 represents an example in which a pressure difference occurs among the plurality of evaporation chambers 61.

In the example represented in FIG. 12, in order to specify each of the plurality of evaporation chambers 61, the plurality of evaporation chambers 61 will be referred to as “evaporation chambers 61A to 61C,” respectively. In order to specify each of the plurality of check valves 41, the plurality of check valves 41 will be referred to as “check valves 41A to 41C,” respectively. In order to specify each of the plurality of steam path branch portions 72, the plurality of steam path branch portions 72 will be referred to as “steam path branch portions 72A to 72C,” respectively.

In the example represented in FIG. 12, the pressure of the evaporation chamber 61A is higher than the pressures of the evaporation chambers 61B and 61C at the time that the evaporation chambers 61A to 6C start to operate. When the pressure of the evaporation chamber 61A is higher than the pressures of the evaporation chambers 61B and 61C as described above, the check valve 41A becomes in the opened state by the refrigerant flowing out from the evaporation chamber 61A, and the check valves 41B and 41C become in the closed state. Accordingly, the reverse flow of the refrigerant from the high pressure evaporation chamber 61A to the low pressure evaporation chambers 61B and 61C is suppressed.

In addition, when the reverse flow of the refrigerant from the high pressure evaporation chamber 61A to the low pressure evaporation chambers 61B and 61C is suppressed, the pressures of the slowly operating evaporation chambers 61B and 61C and the steam path branch portions 72B and 72C which extend from the evaporation chambers 61B and 61C to the check valves 41B and 41C become independent from the pressure of the evaporation chamber 61A. Further, the evaporation of the refrigerants in the evaporation chambers 61B and 61C proceeds independently without being affected from the evaporation chamber 61A, and the pressures of the evaporation chambers 61B and 61C continuously increase.

Then, the check valve 61B is brought into the opened state, and the normal operation of the evaporation chamber 61B is started, at the time that the pressure difference between the evaporation chamber 61A and the evaporation chamber 61B disappears. In the same way, the pressure of the evaporation chamber 61C continuously increases. Then, the check valve 41C is brought into the opened state, and the normal operation of the evaporation chamber 61C is started, at the time that the pressure difference between the evaporation chamber 61A and the evaporation chamber 61C disappears.

In addition, as described above, when the check valves 41A to 41C is brought into the opened state, the refrigerants are circulated between the plurality of evaporation chambers 61 and the condensing chamber 62 so that the heat of the plurality of heat generating bodies 21 is transported by the refrigerants from the plurality of evaporation chambers 61 to the condensing chamber 62. Therefore, the cooling performance for the plurality of heat generation units 21 is assured, and the plurality of heat generating bodies 21 are identically cooled.

Next, the operation and effects of the present embodiment will be described.

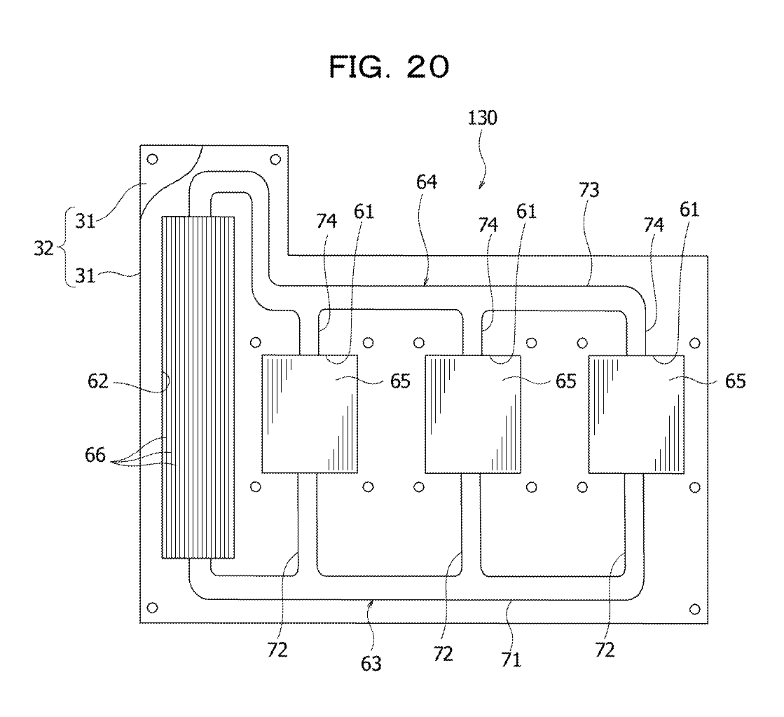

First, a comparative example will be described in order to clarify the operation and effects of the present embodiment. FIG. 20 represents a cooling apparatus 130 according to a comparative example. The cooling apparatus 130 according to the comparative example has a structure which omits the plurality of check valves 41 from the cooling apparatus 30 of the present embodiment (see, e.g., FIG. 3).

In the cooling apparatus 130 according to the comparative example, when the pressure difference occurs among the plurality of evaporation chambers 61 due to the difference in heat flows received by the plurality of evaporation chambers 61, the refrigerant may reversely flow from a high pressure evaporation chamber 61 to a low pressure evaporation chamber 61. When the refrigerant reversely flows from the high pressure evaporation chamber 61 to the low pressure evaporation chamber 61, the reversely flowing refrigerant and the refrigerant flowing out from the low pressure evaporation chamber 61 may interfere with each other, and the boiling of the refrigerant in the low pressure evaporation chamber 61 may be delayed so that the low pressure evaporation chamber 61 may not start to operate smoothly. When the evaporation chamber 61 does not start to operate smoothly, the cooling performance for the heat generating body 21 corresponding to the evaporation chamber 61 may be damaged, and the temperature of the heat generating body 21 may be excessively increased.

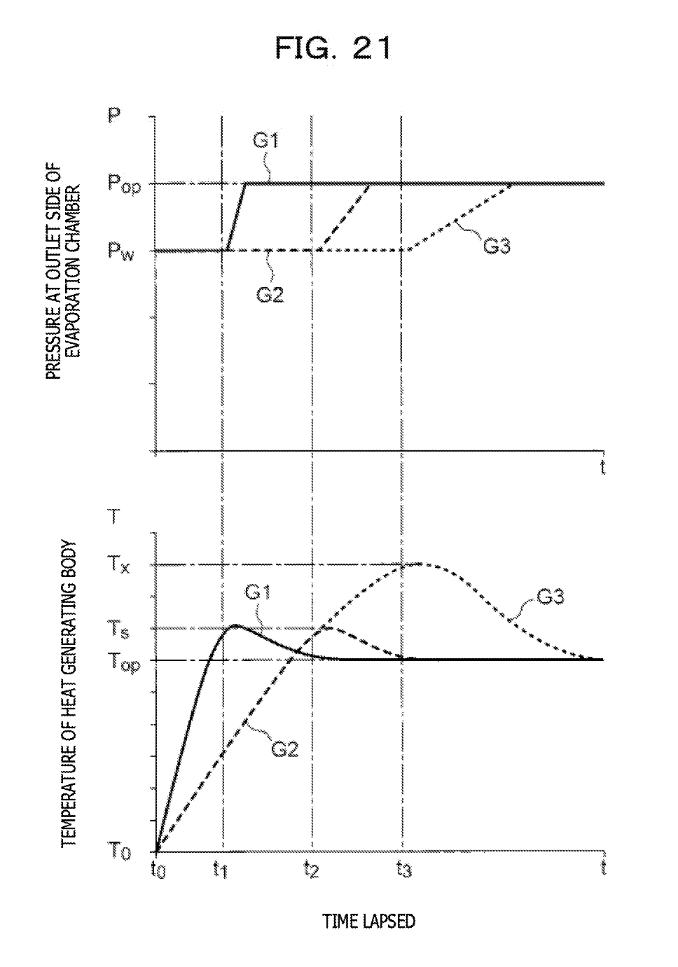

Here, FIG. 21 represents characteristics of the cooling apparatus 130 according to the comparative example. The upper portion of FIG. 21 represents a relationship between the pressures at the outlet sides of the evaporation chambers 61 and time lapsed, and the lower portion of FIG. 21 represents a relationship between the temperatures of the heat generating bodies 21 and time lapsed.

In FIG. 21, time t₀ represents time when the heat generating bodies 21 do not generate heat. At the time t₀, the temperature of each heat generating body 21 is T₀, and the pressure at the outlet side of each evaporation chamber 61 is a pressure P_{w} by the capillary force of the wick 65.

In FIG. 21, the solid line graph G1 represents a case where the pressures of the plurality of evaporation chambers 61 are the same. As represented by the solid line graph G1, when the heat generating bodies 21 start to generate heat, the boiling of the refrigerants in the evaporation chambers 61 is started, and the circulation of the refrigerants is started. Time t₁ represents time when the circulation of the refrigerants is started. As the evaporation chambers 61 are continuously heated by the heat generating bodies 21, the pressures of the evaporation chambers 61 are further increased so that at time t₂, the pressures become stable at P_{OP}, and the temperatures become stable at T_{OP}. In the course in which the heat generating bodies 21 start to generate heat, and then, reach the stable temperature, the temperatures of the heat generating bodies 21 temporarily increase up to the temperature T_{S} which is higher than the stable temperature.

Meanwhile, in FIG. 21, the dashed line graph G2 represents a case where the pressures of the plurality of evaporation chambers 61 are the same, and the heat flow of each heat generating body 21 is smaller than that in the solid line graph G1. In this case, the startup of the evaporation chambers 61 is delayed, compared to the solid line graph G1. Hence, as represented by the dashed line graph G2, the boiling is started at the time t₂ such that the circulation of the refrigerants is started. Thereafter, the pressures become stable at P_{OP}, and the temperatures become stable at T_{OP}.

However, when there is a difference in the heat flows of the plurality of heat generating bodies 21, an evaporation chamber 61 corresponding to a heat generating body 21 having a large heat flow exhibits the behavior of the solid line graph G1, and an evaporation chamber 61 corresponding to a heat generating body 21 having a small heat flow exhibits the behavior of the dotted line graph G3. As described above, the difference in the heat flows of the plurality of heat generating bodies 21 results in a difference in the pressures of the plurality of evaporation chambers 61. Hence, a reverse flow of the refrigerant occurs from a high pressure evaporation chamber 61 to a low pressure evaporation chamber 61.

As a result of the reverse flow of the refrigerant, more time is required for the low pressure evaporation chamber 61 to reach the time t₃ at which the low pressure evaporation chamber 61 becomes in the startup state (the state in which the refrigerant is boiled such that the circulation of the refrigerant is started), and the temperature of the heat generating body 21 increases up to T_{X}. That is, because the cooling performance for the heat generating body 21 corresponding to the low pressure evaporation chamber 61 is damaged, compared to the case where the evaporation chambers 61 starts to operate smoothly as represented by the solid line graph G1 or the dashed line graph G2, the heat generating body 21 is heated up to the relatively higher temperature T_{X}.

In this regard, according to the cooling apparatus 30 of the present embodiment, the check valves 41 are installed in the plurality of steam path branch portions 72, respectively, as illustrated in FIG. 12. In addition, when a pressure difference occurs among the plurality of evaporation chambers 61 due to a difference in heat flows received by the plurality of evaporation chambers 61, a check valve 41 corresponding to a low pressure evaporation chamber 61 becomes in the closed state.

Accordingly, since the reverse flow of the refrigerant from the high pressure evaporation chamber 61 to the low pressure evaporation chamber 61 is suppressed, the interference of the refrigerants between the high pressure evaporation chamber 61 and the low pressure evaporation chamber 61 may be suppressed. Thus, since the low pressure evaporation chamber 61 may start to operate smoothly, the cooling performance for the heat generating body corresponding to the evaporation chamber 61 is assured. As a result, since the temperature of the heat generating body may be suppressed from being excessively increased, the cooling performance for the plurality of heat generating bodies may be assured.

Further, as illustrated in FIG. 9, each check valve 41 is formed as a swing type check valve which includes the plate shaped valve body 42 configured to open and close the steam path 63 and the shaft portion 43 formed along one edge of the valve body 42. Thus, since the check valve 41 is easily miniaturized, the check valve 41 may be easily applied to the thin cooling apparatus 30 even when the cooling apparatus 30 is formed in a thin shape having the laminate 32.

In addition, since the check valve 41 operates by receiving the pressure of the refrigerant, a power source to operate the check valve 41 such as, for example, an actuator is not required. Thus, the thin cooling apparatus 30 may be further miniaturized.

In addition, since the pair of plates 31 forming the laminate 32 are bonded to each other by diffusion bonding, the pair of plates 31 may be precisely bonded to each other, compared to a general bonding by, for example, welding. Accordingly, the dimensional accuracy of the cavities formed inside the laminate 32, especially, the dimensional accuracy between the pair of pivotal support portions 33 may be assured. Thus, the resistance of the shaft portion 43 (the insertion portions 44) may be suppressed from being increased due to an overly narrow distance between the pair of axial support portions 33, or the check valve 41 may be suppressed from being tilted due to an overly wide distance between the pair of pivotal support portions 33 so that the check valve 41 may operate smoothly.

In addition, the pair of plates 31 is formed of a metal, and the check valve 41 is formed of ceramic or carbide. Thus, the check valve 41 may be suppressed from being fixed to the pair of plates 31 at the time of the diffusion bonding of the pair of plates 31. Therefore, the smooth operation of the check valve 41 may be assured.

In addition, the insertion portions 41 are formed in a conically convex shape at the axial opposite ends of the axis portion 43 of the check valve 41 to be inserted into the pivotal support portions 33. The tip ends of the insertion portions 44 are in point-contact with the bottoms of the pivotal support portions 33. Accordingly, the frictional resistance between the insertion portions 44 and the pivotal support portions 33 may be reduced, thereby enabling the check valve 41 to operate smoothly.

In addition, since the check valves 41 are formed of a material having higher hardness than that of the pair of plates 31, the deformation and abrasion of the check valves 41 may be suppressed. Therefore, the smooth operation of the check valves 41 may be maintained.

In addition, since the shaft portion 43 of each check valve 41 extends in the thickness direction of the thin laminate 32, the length of the shaft portion 43 may be made short. Accordingly, a dimensional tolerance of the shaft portion 43 may be reduced.

In addition, as illustrated in FIG. 4, the steam path 63 is thin and has a large width, and the dimension of the steam path 63 W in the width direction is larger than the dimension of the steam path 63 H in the height direction. Thus, the space in the width direction of the steam path 63 may be more easily secured than the space in the height direction of the steam path 63. Therefore, as illustrated in FIG. 9, the protruding length of the valve body 43 from the shaft portion 43 may be easily secured in the width direction of the steam path 63.

In addition, as illustrated in FIG. 10, the shaft portion 43 is disposed at one side of the steam path 63 in the width direction thereof. Meanwhile, the valve body 42 extends from the shaft portion 43 toward the other side of the steam path 63 in the width direction thereof in the closed state, and is formed in a rectangular shape of which a longitudinal direction is orthogonal to the axis direction of the shaft portion 43. Thus, as the length of the valve body 42 in the longitudinal direction thereof is long, the moment acting on the check valve 41 increases when the pressure of the refrigerant acts on the valve body 42 so that the responsiveness of the check valve 41 may be improved.

In addition, since the thickness of the valve body 42 is thinner than the diameter of the shaft portion 43, the inertial force acting on the valve body 42 may be reduced. Thus, this may also enable the improvement of the responsiveness of the check valve 41.

In addition, when the check valve 41 is brought into the opened state, the angle of the check valve 41 is regulated to be inclined by the regulation portion 85 so that the portion 47 of the tip end side of the valve body 42 is spaced apart from one side surface 81 of the steam path branch portion 72. Accordingly, when the refrigerant reversely flows, the refrigerant flows into between the check valve 41 and the side surface 81 so that the check valve 41 is quickly closed. Therefore, the reverse flow of the refrigerant may be more effectively suppressed.

In addition, as a method of implementing the pressure balance of the respective steam path branch portions 72 without providing the check valves 41, it may be taken into account to design various evaporation chambers according to various forms or heat flows of the plurality of heat generating bodies. However, such a separate design increases costs. When the check valves 41 are installed as in the present embodiment, the evaporation chambers may have substantially the same structure, and no cost increase occurs.

Next, modifications of the present embodiment will be described.

### First Modification

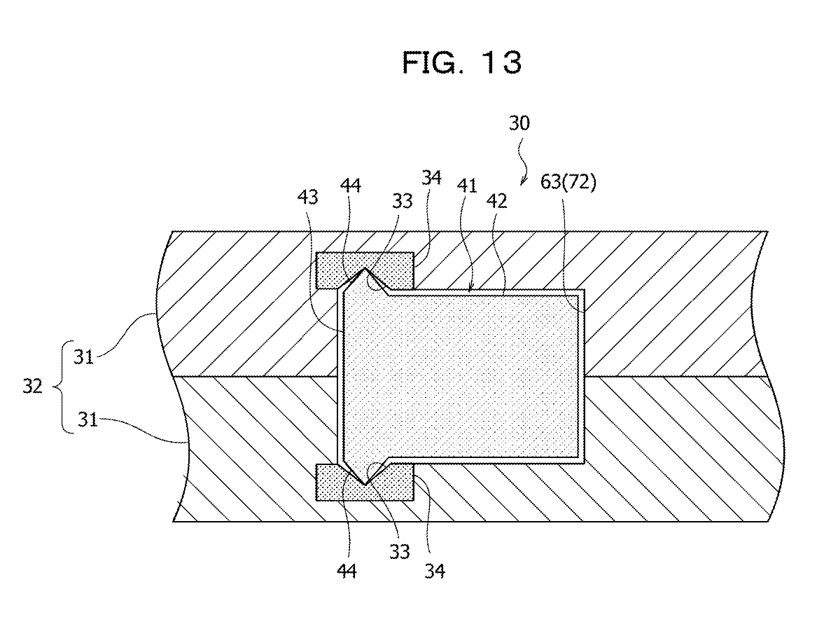

In the above-described embodiment, as illustrated in FIG. 7, the pivotal support portions 33 are formed in the pair of plates 31. However, as illustrated in FIG. 13, the pivotal support portions 33 may be formed in pivotal support members 34 installed separately from the pair of plates 31.

In addition, the pivotal support members 34 provided with the pivotal support portions 33 and the check valve 41 provided with the shaft portion 43 may be formed of ceramic or carbide. As described above, when the pivotal support portions 33 and the shaft portion 43 are formed of ceramic or carbide, the abrasion of the pivotal support portions 33 and the shaft portion 43 may be suppressed, and the durability thereof may be improved.

### Second Modification

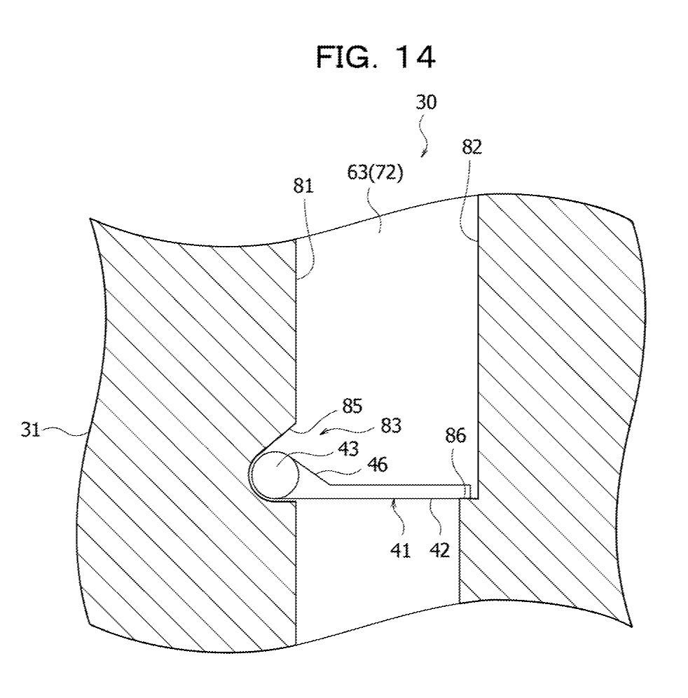

In the above-described embodiment, as illustrated in FIG. 10, there is a gap between the tip end of the valve body 42 and the other side surface 82 of the steam path 63 when the check valve 41 is in the closed state. However, as illustrated in FIG. 14, a step shaped stopper portion 86 may be formed on the other side surface 82 of the steam path 63 so as to be in contact with the tip end of the valve body 42 in the closed state of the check valve 41. As described above, when the stopper portion 86 regulating the closed position of the check valve 41 is in contact with the tip end of the valve body 42, it is possible to suppress the formation of the gap between the tip end of the valve body 42 and the side surface 82 of the steam path 63. Therefore, the reverse flow of the refrigerant may be more effectively suppressed.

### Third Modification

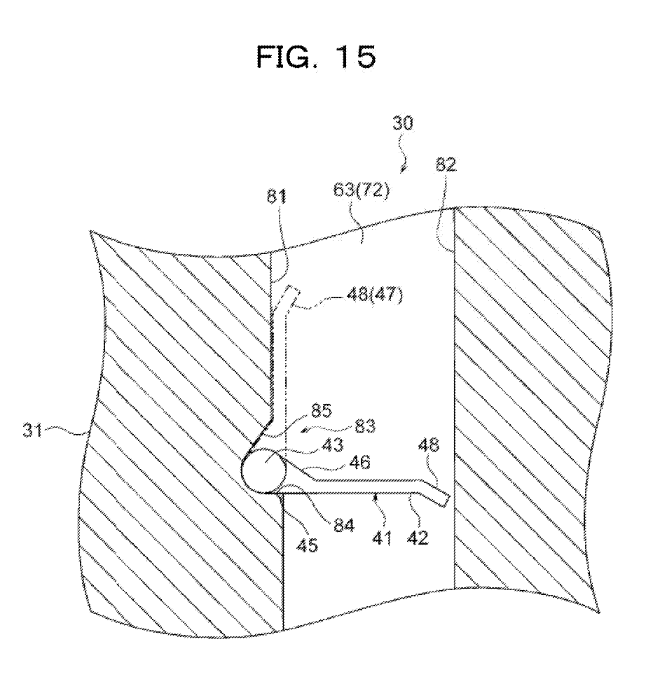

In the above-described embodiment, as illustrated in FIG. 10, the angle of the check valve 41 is regulated to be inclined by the regulation portion 85 when the check valve 41 is brought into the opened state. However, as illustrated in FIG. 15, when the check valve 41 is brought into the opened state, the check valve 41 may be arranged along the side surface 81.

In addition, as illustrated in FIG. 15, a bent portion 48 may be formed at the portion 47 of the tip end side of the valve body 42 so as to be spaced apart from the side surface 81 in the opened state of the check valve 41. Even with this configuration, when the refrigerant reversely flows, the refrigerant flows into between the bent portion 48 and the side surface 81 so that the check valve 41 may be quickly closed.

In addition, in the above-described embodiment, as illustrated in FIG. 10, when the check valve 41 is brought into the opened state, the portion 47 of the tip end side of the valve body 42 is spaced apart from the side surface 81 of the steam path branch portion 72, compared to the surface 46 of the other side of the valve body 42. However, when the check valve 41 is brought into the opened state, the entire valve body 42 may be formed to be spaced apart from the one side surface 81 of the steam path branch portion 72.

### Fourth Modification

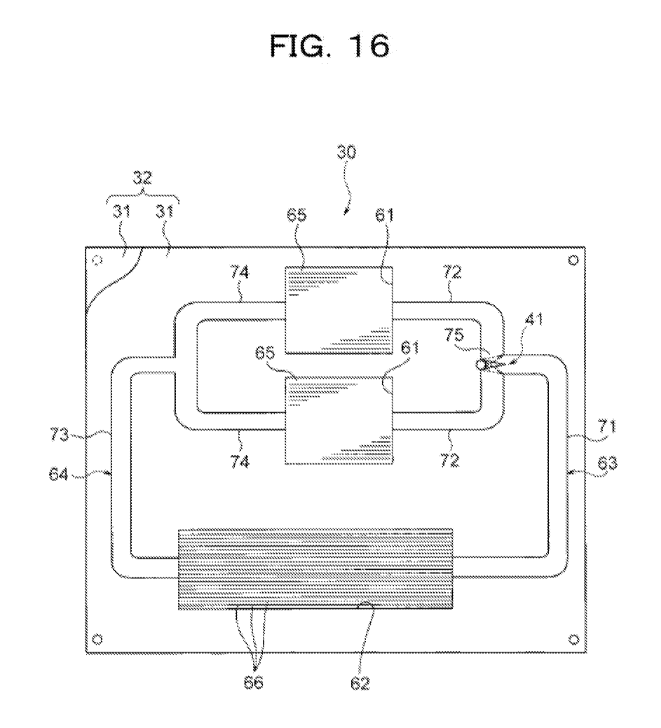

In the above-described embodiment, the check valves 41 are installed in the plurality of steam path branch portions 72, respectively, as illustrated in FIGS. 2 and 3. However, for example, as illustrated in FIG. 16, when the pair of steam path branch portions 72 joins with each other at a joining portion 75, a check valve 41 may be installed at the joining portion 75. When the check valve 41 is installed at the joining portion 75, the number of the check valves 41 may be reduced, compared to the case where the check valves 41 are provided in the plurality of steam path branch portions 72, respectively. Therefore, the structure of the cooling apparatus 30 may be simplified and miniaturized.

In addition, in the example represented in FIG. 16, when the heat flows received by the pair of evaporation chambers 61 are the same, no pressure difference occurs at the outlet sides of the pair of evaporation chambers 61. In addition, the check valve 41 is disposed in the middle position between the evaporation chambers 61 such that a discharge of the refrigerants from both the evaporation chambers 61 is implemented. Meanwhile, when a pressure difference occurs in the pair of evaporation chambers 61, the check valve 41 is rotated toward a low pressure evaporation chamber 61 side so that the reverse flow of the refrigerant into the low pressure evaporation chamber 61 is suppressed.

### Fifth Modification

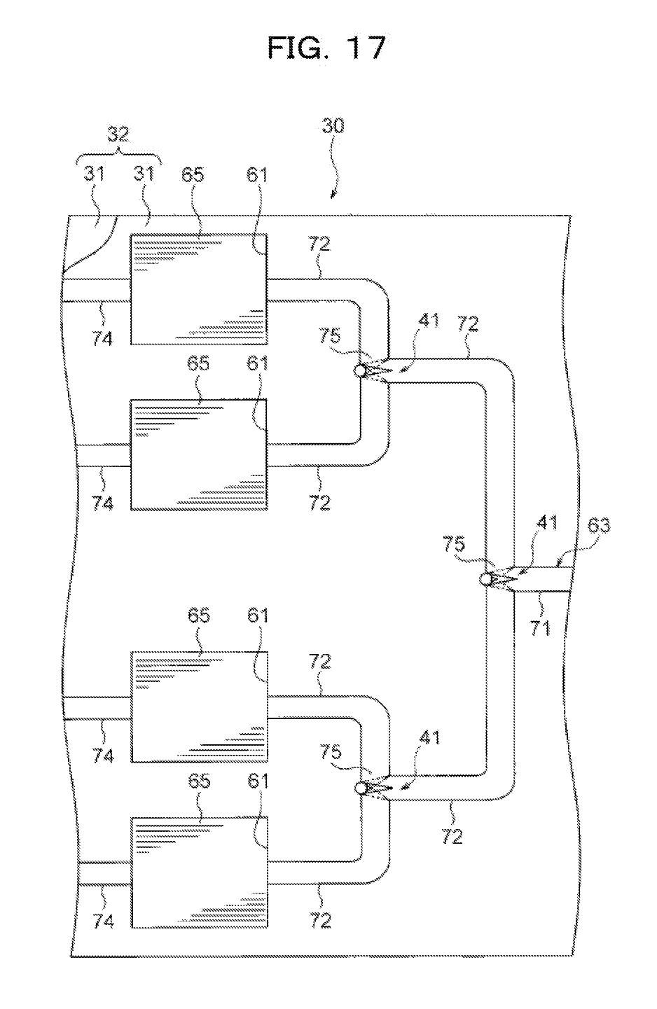

In addition, as illustrated in FIG. 17, the steam path 63 may include steam path branch portions 72 which are further branched from the plurality of steam path branch portions 72. In this case, a check valve 41 may be installed at a joining portion 75 of each pair of steam path branch portions 72. In this configuration as well, the reverse flow of the refrigerant from a high pressure evaporation chamber 61 to a low pressure evaporation chamber 61 may be suppressed.

### Sixth Modification

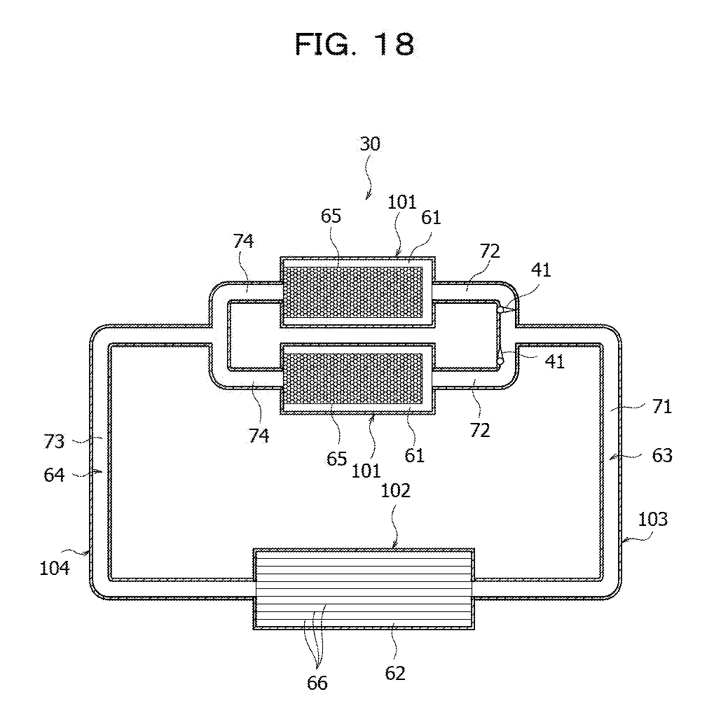

In the above-described embodiment, as illustrated in FIGS. 2 and 3, the cooling apparatus 30 has a flat plate shape, and the plurality of evaporation chambers 61, the steam path 63, the condensing chamber 62, and the liquid path 64 are formed in the laminate 32. However, as illustrated in FIG. 18, the cooling apparatus 30 may be provided as a loop heat pipe. Further, each of the plurality of evaporation chambers 61 may be formed in an evaporator 101, the condensing chamber 62 may be formed in a condenser 102, the steam path 63 may be formed in a steam pipe 103, and the liquid path 64 may be formed in a liquid pipe 104.

### Other Modifications

In the above-described embodiment, as illustrated in FIGS. 2 to 4, the laminate 32 is formed by the pair of plates 31. However, the number of the plurality of plates 31 forming the laminate 32 may be three or more. Further, the thicknesses of the plurality of plates 31 may be the same or different from each other. The depths of the recesses 51 and 52 and the grooves 53 and 54 which are formed in each of the plurality of plates 31 may also be different from each other depending on each plate 31.

In addition, in the above-described embodiment, the recesses 51 and 52 and the grooves 53 and 54 are formed in each of the pair of plates 31. However, one plate 31 may be formed in a flat plate shape, and the other plate 31 may be provided with the recesses 51 and 52 and the grooves 53 and 54. In addition, the recesses 51 and 52 and the grooves 53 and 54 may be formed by being distributed in one plate 31 and the other plate 31.

In addition, in the above-described embodiment, the cooling apparatus 30 includes the three evaporation chambers 61. However, the number of the plurality of evaporation chambers 61 is not limited. In addition, in the above-described embodiment, the heat generating bodies 21 which are objects to be cooled by the cooling apparatus 30 are, for example, electronic parts. However, the objects to be cooled by the cooling apparatus 30 may be heat generating bodies other than electronic parts. In addition, the objects to be cooled by the cooling apparatus 30 may be, for example, a single heat generating body including a plurality of heat generating parts, rather than the plurality of heat generating bodies 21.

In addition, when the objects to be cooled by the cooling apparatus 30 are a single heat generating body including a plurality of heat generating parts, the plurality of evaporation chambers 61 may be arranged to correspond to the plurality of heat generating parts (heat generating areas) in the single heat generating body.

In addition, in the above-described embodiment, as illustrated in FIG. 9, the check valve 41 is disposed such that the shaft portion 43 extends in the thickness direction of the laminate 32. However, the check valve 41 may be disposed such that the shaft portion 43 extends in the horizontal direction of the laminate 32.

In addition, among the plurality of modifications described above, modifications which may be subject to combination may be appropriately combined with each other so as to be implemented.

All examples and conditional language recited herein are intended for pedagogical purposes to aid the reader in understanding the disclosure and the concepts contributed by the inventor to furthering the art, and are to be construed as being without limitation to such specifically recited examples and conditions, nor does the organization of such examples in the specification relate to a showing of the superiority and inferiority of the disclosure. Although the embodiments of the present disclosure have been described in detail, it should be understood that the various changes, substitutions, and alterations could be made hereto without departing from the spirit and scope of the disclosure.

What is claimed is:

1. A cooling apparatus comprising:
a plurality of evaporation chambers in which a refrigerant is accommodated;
a steam path including a plurality of steam path branch portions which extend from the plurality of evaporation chambers, respectively, and a steam path body portion in which the plurality of steam path branch portions join with each other;
a condensing chamber coupled to the plurality of evaporation chambers through the steam path;
a liquid path including a liquid path body portion which extends from the condensing chamber, and a plurality of liquid path branch portions, which are branched from the liquid path body portion to be coupled to the plurality of evaporation chambers, respectively; and
a check valve installed in the steam path and suppresses a reverse flow of the refrigerant from one evaporation chamber to another evaporation chamber among the plurality of evaporation chambers.

2. The cooling apparatus according to claim 1, further comprising:
a laminate in which a plurality of plates are laminated,
wherein the plurality of evaporation chambers, the steam path, the condensing chamber, and the liquid path are formed by cavities formed inside the laminate.

3. The cooling apparatus according to claim 2, wherein the check valve is a swing type check valve including a plate shaped valve body that opens and closes the steam path and a shaft portion formed along one edge of the valve body.

4. The cooling apparatus according to claim 3, wherein the check valve operates by receiving a pressure of the refrigerant.

5. The cooling apparatus according to claim 2, wherein the plurality of plates are bonded to each other by diffusion bonding.

6. The cooling apparatus according to claim 5, wherein the plurality of plates are formed of a metal and
the check valve is formed of ceramic or carbide.

7. The cooling apparatus according to claim 2, wherein a pivotal support portion having a conically concave shape installed in the plurality of plates, an insertion portion having a conically convex shape is formed at each of opposite ends of the shaft portion to be inserted into the pivotal support portion, and the shaft portion is rotatably supported by the pivotal support portion in a state in which a tip end of the insertion portion is in point-contact with a bottom of the pivotal support portion.

8. The cooling apparatus according to claim 7, wherein the check valve is formed of a material having higher hardness than that of the plurality of plates.

9. The cooling apparatus according to claim 7, wherein the pivotal support portion and the shaft portion are formed of ceramic or carbide.

10. The cooling apparatus according to claim 2, wherein the shaft portion extends in a thickness direction of the laminate.

11. The cooling apparatus according to claim 10, wherein a dimension of the steam path in a width direction is larger than a dimension of the steam path in a height direction.

12. The cooling apparatus according to claim 11, wherein the shaft portion is disposed at one side of the steam path in a width direction thereof, and the valve body extends from the shaft portion toward the other side of the steam path in the width direction thereof in a closed state of the check valve and has a rectangular shape of which a longitudinal direction is orthogonal to an axial direction of the shaft portion.

13. The cooling apparatus according to claim 10, wherein a thickness of the valve body is thinner than a diameter of the shaft portion.

14. The cooling apparatus according to claim 3, wherein an inner wall surface of the steam path is provided with a stopper portion which is in contact with the valve body in the closed state of the check valve.

15. The cooling apparatus according to claim 14, wherein the stopper portion is in contact with a tip end of the valve body.

16. The cooling apparatus according to claim 3, wherein the steam path is formed in a square shape in cross section, the check valve is brought into an opened state by being rotated in a direction approaching one of four inner wall surfaces forming the square shape of the steam path in cross section, and at least the tip end of the valve body is spaced apart from the one inner wall in the opened state of the check valve.

17. The cooling apparatus according to claim 1, further comprising:
a plurality of evaporators forming the plurality of evaporation chambers, respectively;
a steam pipe forming the steam path;
a condenser forming the condensing chamber; and
a liquid pipe forming the liquid path.

18. The cooling apparatus according to claim 1, wherein the plurality of steam path branch portions include a pair of steam path branch portions which join with each other in a joining portion, and the check valve is provided in the joining portion.

19. The cooling apparatus according to claim 1, wherein the check valve is installed in each of the plurality of steam path branch portions.

20. An electronic equipment comprising:
a plurality of heat generation units; and
a cooling apparatus cools the plurality of heat generation units,
wherein the cooling device including
a plurality of evaporation chambers installed to correspond to the plurality of heat generation units, respectively, a refrigerant being accommodated in the plurality of chambers,
a steam path including a plurality of steam path branch portions which extend from the plurality of evaporation chambers, respectively, and a steam path body portion in which the plurality of steam path branch portions join with each other,
a condensing chamber coupled to the plurality of evaporation chambers through the steam path,
a liquid path including a liquid path body portion which extends from the condensing chamber, and a plurality of liquid path branch portions, which are branched from the liquid path body portion to be coupled to the plurality of evaporation chambers, respectively, and
a check valve installed in the steam path and suppresses a reverse flow of the refrigerant from one evaporation chamber to another evaporation chamber among the plurality of evaporation chambers.
